(19) United States
(12) Patent Application Publication
(10) Pub. No.: US 2009/0242961 A1
(43) Pub. Date: Oct. 1, 2009

(54) RECESSED CHANNEL SELECT GATE FOR A MEMORY DEVICE

(76) Inventors: Sanh Tang, Boise, ID (US); Max Hineman, Boise, ID (US); Kyu Min, San Jose, CA (US); Luan Tran, Meridian, ID (US)

Correspondence Address: COOL PATENT, P.C.;c/o CPA Global, P.O. BOX 52050, MINNEAPOLIS, MN, 55402, US

(21) Appl. No.: 12/059,024

(22) Filed: Mar. 31, 2008

(51) Int. Cl. H01L 29/792; H01L 21/336

(52) U.S. Cl. 257/324; 438/259; 438/261; 257/E29.309; 257/E21.409

(57) ABSTRACT

A memory device comprising one or more recessed channel select gates and at least one charge trapping layer.

### BACKGROUND

Electrically-erasable programmable read only memory (EEPROM) devices may be used for many purposes in present day digital circuits such as computers because of their ability to retain data when power is removed and to be easily reprogrammed. A flash EEPROM device may store electrical charge representing data in a floating gate. Alternatively, charge may be stored in charge trapping layer wherein a control gate layer may be formed over the charge trapping layer. The charge stored on the floating gate or in the charge trapping layer may be changed by programming and the condition (programmed or erased) may be detected.

### BRIEF DESCRIPTION OF THE DRAWINGS

FIG. 1 is a plan view of a particular embodiment of a non-volatile memory device comprising a recessed channel select gate.

FIG. 2 is a sectional view of a particular embodiment of a non-volatile memory device comprising a recessed channel select gate taken along cut line 1A-1A of FIG. 1.

FIG. 3 is a block diagram illustrating a process for making a particular embodiment of a non-volatile memory device comprising a recessed channel select gate.

### DETAILED DESCRIPTION

In the following detailed description, numerous specific details are set forth in order to provide a thorough understanding of claimed subject matter. However, it will be understood by those skilled in the art that claimed subject matter may be practiced without these specific details. In other instances, well-known methods, procedures, and components have not been described in detail so as not to obscure claimed subject matter.

Throughout the following disclosure the term ‘NAND’ is used and is intended to refer to the logic function ‘not-AND’. The term ‘NAND flash’ is used throughout the disclosure and is intended to refer to a flash EEPROM device that employs tunnel injection for writing and tunnel release for erasing.

Charge trapping memory devices may have benefits over conventional memory devices such as improved scaling at sub-50 nm regime and improved data retention. However, in conventional processing charge trapping layers share a gate dielectric with select gate transistors in each block of memory devices. Using the same charge trapping layers as gate dielectrics may cause device failures due to a reduced ability to modulate select gates along the memory device. Using charge trapping layers as the gate dielectric for a select gate may generate reliability issues because charges may accumulate through operating cycles. Also, defining the select gate prior to depositing charge trapping layers may create topography impacts on the subsequent cell array patterning.

FIG. 1 is a plan view of a particular embodiment of memory device 100 comprising recessed channel select gates (RCSG) 108. In a particular embodiment, memory device 100 may be a variety of memory devices comprising a charge trapping layer, such as, for instance, an EEPROM memory device, flash EEPROM memory device and/or NAND flash EEPROM memory device and claimed subject matter is not limited in this regard. In a particular embodiment, memory device 100 may comprise memory array 102, periphery region 104, field effect transistor (FET) word line 106, RCSGs 108, peripheral field effect transistor (FET) 110 and shallow trench isolation (STI) 112. In a particular embodiment, FET 110 may be a complimentary metal-oxide semiconductor (CMOS). According to a particular embodiment, word lines 106 may comprise charge trapping layers and RCSGs 108 may be disposed in recessed channels 123 of substrate 120. Such RCSG 108 may enable scaling of memory devices, such as CTF, at sub-50 nm regime.

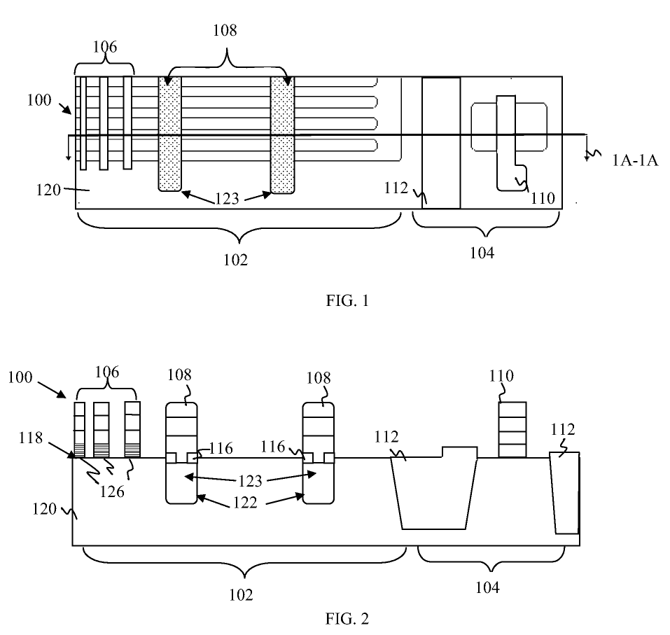

In contrast to conventional memory devices, in memory device 100 RCSGs 108 may enable separating charge trapping layers and select gates by disposing RCSG 108 in recessed channels 123 such that each feature may have distinct gate dielectrics. FIG. 2 depicts a cross section through cut line 1A-1A of memory device 100 showing distinct gate dielectrics of charge trapping layers and recessed channel select gates.

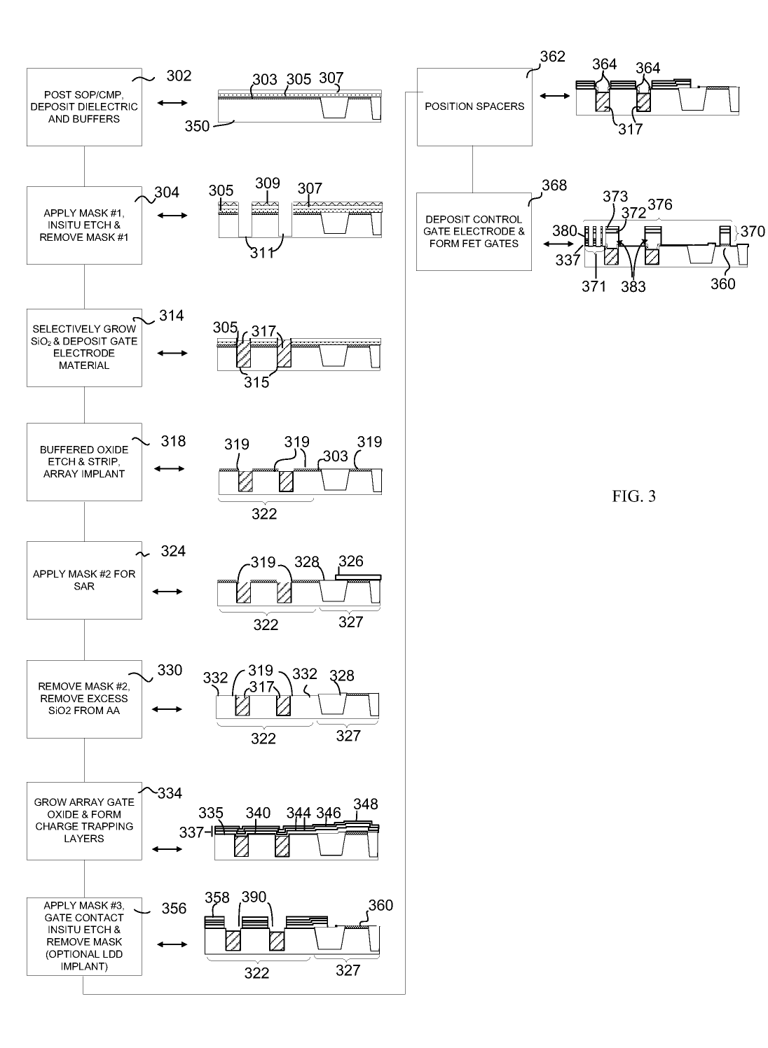

FIG. 2 illustrates a cross sectional view through cut line 1A-1A of FIG. 1 of a particular embodiment of memory device 100 comprising recessed channel select gates 108. In a particular embodiment, memory device 100 may comprise memory array 102 and periphery region 104. In a particular embodiment, memory array 102 may comprise word line 106, charge trapping layers 118, RCSG 108, recessed channel select gate dielectric 122 and spacers 116. According to a particular embodiment, peripheral region 104 may comprise peripheral field effect transistor (FET) 110 and shallow trench isolation (STI) 112. In a particular embodiment, RCSGs 108 may be disposed within recessed channels 123 etched into substrate 120 and may comprise RCSG dielectric 122 which may separate charge trapping layers (shown in FIG. 2 at 118) from RCSG 108. FIG. 3 illustrates a particular embodiment of a process to form memory device 100.

FIG. 3 illustrates a block diagram of a particular embodiment of a process 300 for making a memory device 100 comprising recessed channel select gates (RCSG). Each block has an illustration of the process step showing a cross section of memory device 100 as depicted in FIG. 2.

Process 300 is merely an example of a process to form memory device 350. There may be a variety of methods of making memory device 350 comprising recessed channel select gates. For instance, in a particular embodiment a recessed channel may be defined before formation of an array's shallow trench isolation (STI) features or after an array word line is defined and claimed subject matter is not limited in this regard.

In a particular embodiment, process 300 may begin at block 302 after spin on polymer (SOP), chemical vapor deposition (CVD) and chemical mechanical polishing (CMP) process stages have taken place. In a particular embodiment, at block 302 a layer of first dielectric layer 303 may be deposited. According to a particular embodiment, first dielectric layer 303 may comprise a variety of materials, such as silicon dioxide and claimed subject matter is not so limited. According to a particular embodiment, variety of techniques may be used to deposit first dielectric layer 303, such as, plasma enhanced chemical vapor deposition (PECVD), and/or chemical vapor deposition (CVD) and claimed subject matter is not so limited. In a particular embodiment, first dielectric layer 303 may be formed to a depth of about 400 A or any appropriate depth as may be determined by one of ordinary skill in the art and claimed subject matter is not so limited.

In a particular embodiment, process 300 may continue at block 302 where a buffer layer 305 and a bottom anti-reflective coating (BARC) 307 may be applied. In a particular embodiment, buffer 305 may comprise a variety of materials such, nitride, silicon nitride, amorphous carbon and/or transparent carbon and claimed subject matter is limited in this regard. According to a particular embodiment, buffer 305 may be deposited by a variety of methods such as, for instance, CVD and/or PECVD and claimed subject matter is not so limited.

In a particular embodiment, BARC 307 may comprise a variety of materials such, silicon nitride, silicon oxynitride, titanium nitride, silicon carbide and amorphous silicon and claimed subject matter is not limited in this regard. According to a particular embodiment, BARC 307 may be deposited by a variety of methods such as, for instance, CVD, PECVD and/or spin-on-resin (SOR) and claimed subject matter is not so limited. In another particular embodiment, process 300 may proceed without depositing a buffer 305 or BARC 307 and claimed subject matter is not limited in this regard.

In a particular embodiment, process 300 may proceed to block 304 where mask 309 may be formed on BARC 307 and may define where recessed channels (RC) 311 may be formed. Thereafter, an insitu etch, such as, reactive-ion-etch (RIE) may be performed to define RCs 311. However, this is merely a method of forming recessed channels in a substrate and as mentioned above recessed channel select gates may be formed by using a variety of methods at various process steps and claimed subject matter is not limited in this regard.

In a particular embodiment, RCs 311 may be recessed to a depth of about 1000 ↑ to about 1,500 Å or any depth as may be determined appropriate by one skilled in the art. According to a particular embodiment, insitu etch may be continuous by trenching STI and silicon at the same time or insitu etch may recess only silicon. In a particular embodiment, recessing silicon only may provide a higher degree of isolation

In a particular embodiment, process 300 may flow to block 314 where mask 309 may be removed. According to a particular embodiment, second dielectric layer 315 may be selectively grown on the inner surfaces of RCs 311 by a variety of methods such as oxidation, and/or a combination of oxidation and deposition. In a particular embodiment, second dielectric layer 315 may comprise a variety of materials such as silicon-nitride (SiN), hafnium oxide (HfOx), aluminum oxide (AlOx) and/or zirconium oxide (ZrOx) and claimed subject matter is not limited in this regard. In a particular embodiment, second dielectric layer 315 may be grown to a thickness of about 50 Å to about 100 Å or any thickness as may be determined to be appropriate by one skilled in the art. This is merely an example of a second dielectric layer that may be grown on an inner surface of RCSGs in a memory device and claimed subject matter is not so limited.

In a particular embodiment, after second dielectric layer 315 is grown, recessed channel select gate contact 317 may be deposited within RCs 311. According to a particular embodiment, RCSG contact 317 may comprise a variety of materials such as Insitu-doped (ISD) polysilicon, N+ polysilicon, titanium nitride (TiN) and/or tantalum nitride (TaN) and claimed subject matter is not so limited.

According to a particular embodiment, RCSG contact 317 may be etched to just below the level of buffer 305 by a variety of methods such, for instance, wet etch, and/or blanket RIE dry etch and claimed subject matter is not so limited. In a particular embodiment, such etching may stop at or just below buffer 305 level and claimed subject matter is not so limited. In a particular embodiment, buffer 305 may enable RCSG contact 317 material to stay above first dielectric layer 303 level. However, this is merely an example of a method of forming select gate electrodes in recessed channels and claimed subject matter is not so limited.

In a particular embodiment, process 300 may proceed to block 318 where a selective etch and strip may be performed to selectively remove buffer 305 and may expose first dielectric layer 303 in active areas 319. In a particular embodiment, RCSG contact 317 may be extend above first dielectric layer 303 over active area 319 enabling planarization of RCSG contact 317. According to a particular embodiment, such selective etch and strip may enable thinning of standing RCSG contact 317 along active areas 319. However, this is merely an example of a method of removing a buffer layer and claimed subject matter is not so limited.

According to a particular embodiment, after selective etch and strip is performed an enhancement implant may be performed on array 322. Such an enhanced implant may be performed to dope recessed channels 311 and 313 for voltage threshold (Vt) optimization

In a particular embodiment, process 300 may proceed to block 324 where mask 326 may be applied to periphery 327 for protection during an array 322 strip and regrow (SAR) process stage. According to a particular embodiment, process 300 may continue at block 324 where insitu STI may proceed to remove unmasked portions of STI oxide 328. According to a particular embodiment, first dielectric layer 303 in active area 319 may be removed by etching also. According to a particular embodiment, by over etching, RCSG contact 317 may be set to about +/−100 A with respect to active area 319 surface. However, this is merely an example of a method of setting RCSG electrodes and claimed subject matter is not so limited.

In a particular embodiment, process 300 may proceed to block 330 where second mask 326 may be removed and a gate oxide pre-clean may be performed. During gate oxide pre-clean, remaining second dielectric layer 315 over active areas 319 may be removed. In a particular embodiment, second dielectric layer 315 may be removed by a variety of methods such as wet clean using hydrofluoric acid (HF) and claimed subject matter is not limited in this regard. Such a cleaning step may prepare silicon surface 332 for tunnel gate oxidation.

In a particular embodiment, process 300 may proceed to block 334 wherein an array tunnel gate oxide 335 may be grown. Such array tunnel oxide 335 may be grown over any exposed polysilicon on memory device 350. According to a particular embodiment, array gate oxide 335 may comprise a dielectric layer for charge trapping layers 337 formed latter in process 300. However, this is merely an example of a method of growing an array tunnel gate oxide and claimed subject matter is not so limited.

According to a particular embodiment, process 300 may continue in block 334 where charge trapping layers 337 may be formed. In a particular embodiment, charge trapping layers 337 may comprise a TANOS (tantalum, alumina, nitride, oxide, silicon) stack comprising a nitride layer 340, buffer layers 344, metal gate 346 and a thin polysilicon cap 348. Such a TANOS stack may comprise, for example, SiN/Al2O3/TaN. However, in another particular embodiment, charge trapping layers 337 may comprise a SONOS (silicon-oxide-nitride-oxide-silicon) stack comprising Oxide/Nitride/Oxide and claimed subject matter is not so limited.

In a particular embodiment, process 300 may proceed to block 352 where third mask 358 may be applied to define contacts in periphery 327 and contacts over RCSG contact 317 of RCs 311 such that a margin 390 is defined about RCs 311. According to a particular embodiment, an etching stage, such as, a gate contact insitu etch may follow. Such an etching stage may expose peripheral gate 360 and RCSG contact 317. In a particular embodiment, exposed; charge trapping layers 337, metal gate 346 and/or thin polysilicon cap 348 may all be substantially removed. According to a particular embodiment, RIE etch may stop on gate oxides of peripheral gate 360 and RCSG contact 317. In a particular embodiment, etch stop may be applied to RSCG contact 317 to prevent damage to corners.

In a particular embodiment, angled lightly doped drain (LDD) implant may be introduced here to connect RCSG contact 317 with future source and drain (S/D) regions (not shown). According to a particular embodiment, S/D regions may reside between the first and last word lines 371 and/or between RCs 311. In a particular embodiment, LDD implant may be done before or after third mask 358 is removed. However, this is merely an example of a method of defining contact regions in a memory device and claimed subject matter is not so limited.

In a particular embodiment, process 300 may proceed to block 362 where one or more spacers 364 may be formed. Such spacers 364 may separate charge trapping layers 337 from RCSG contacts 317 and may protect second dielectric layer 315 adjacent to RCSG contact 317 from a subsequent wet etch process stage. In a particular embodiment, such spacers may comprise a variety of materials such as, for instance tetra-ethyl-ortho-silicate (TEOS) and claimed subject matter is not limited in this regard.

According to a particular embodiment, spacer 364 may act as self-align features for a gate strap formed at a later processing stage using low resistance metals, such as, titanium nitride (TiN), tantalum nitride (TaN), titanium silicide (TiSix), nickel silicide (NiSix), cobalt silicide (CoSix), tungsten silicide (WSix), and/or tungsten (W). However, this is merely an example of a method of forming spacers in a memory device and claimed subject matter is not so limited.

In a particular embodiment, spacer 364 may have a thickness such that it may leave an opening (not shown) about 10 nm-40 nm in diameter in RCSG contact 317 for formation of gate strap contacts at a later processing stage. According to a particular embodiment, spacer 364 may be over-etched at about 100 A. Subsequent pre-polysilicon deposition of spacer 364 may substantially clear residual oxide and may increase an opening in RCSG contact 317 up to another 10 nm in diameter. In a particular embodiment, spacer 364 may protect adjacent silicon from exposure to subsequent control gate conductors and may enable RCSG contact 317 self-alignment and critical dimension margin. However, this is merely an example of a method of forming spacers in a memory device and claimed subject matter is not so limited.

In a particular embodiment, process 300 may proceed to block 368 where control gate stack 370 may be deposited. In a particular embodiment, control gate stack 370 may comprise a number of layers, such as, for instance, polysilicon layer 380 disposed over charge trapping layer 337, metal layer 372 disposed over polysilicon layer 380 and TEOS layer 373 disposed over metal 372 layer. In a particular embodiment, polysilicon layer 380 may comprise doped or undoped polysilicon and claimed subject matter is not limited in this regard. According to a particular embodiment, metal layer 372 may comprise a variety of metals and may be metal and/or polysilicon/metal and claimed subject matter is not limited in this regard.

In a particular embodiment, process 300 may continue at block 368 where field effect transistor (FET) gates 376 may be formed from control gate stack 370. In a particular embodiment, FET gates may be formed by etching control gate stack 370. According to a particular embodiment, FET gates formed at this process stage may include RCSG 383, array word line 371, and peripheral gates 360. In a particular embodiment, FET gates 376 may be defined simultaneously. In a particular embodiment, process 300 may subsequently continue onto conventional interconnection processes.

While certain features of claimed subject matter have been illustrated as described herein, many modifications, substitutions, changes and equivalents will now occur to those skilled in the art. It is, therefore, to be understood that the appended claims are intended to cover all such embodiments and changes as fall within the spirit of claimed subject matter.

What is claimed is:

1. A memory device comprising:
a substrate;
a recessed channel disposed within the substrate;
a charge trapping layer disposed on the substrate;
a select gate formed on the recessed channel wherein the charge trapping layer is substantially not in electrical contact with the recessed channel select gate; and
a word line disposed over the charge trapping layer.

2. The memory device of claim 1 further comprising a spacer disposed between a recessed channel select gate contact and the charge trapping layer.

3. The memory device of claim 2 wherein the spacer comprises tetra-ethyl-ortho-silicate (TEOS) or silicon nitride, or combinations thereof.

4. The memory device of claim 2 wherein the spacer substantially separates the charge trapping layer from a contact of the recessed channel select gate.

5. The memory device of claim 1 wherein the word line comprises;
a polysilicon layer disposed over the charge trapping layer;
a metal layer disposed over the polysilicon layer; and
a tetra-ethyl-ortho-silicate (TEOS) layer disposed over the metal layer.

6. The memory device of claim 1 wherein the charge-trapping layer comprises:
a first dielectric material;
a charge-trapping material formed over the first dielectric material; and
an second dielectric formed over the charge-trapping material.

7. The memory device of claim 1 wherein the charge-trapping layer comprises:
a first oxide material;
a nitride material formed over the first oxide material; and
a second oxide material formed over the nitride material.

8. The memory device of claim 1 wherein a recessed channel select gate contact is disposed within the recessed channel.

9. The memory device of claim 5 wherein the recessed channel select gate contact comprises; Insitu-doped (ISD) polysilicon, N+ polysilicon, titanium nitride (TiN) or tantalum nitride (TaN), or combinations thereof.

10. The memory device of claim 1 wherein the recessed channel comprises a depth of about 1.0-1.5 kA.

11. A method of forming memory device comprising:
forming a recessed channel within a substrate;
depositing a contact material within recessed channel to form a select gate electrode;
forming a charge trapping layer on the substrate;
masking charge trapping layer to define recessed channel select gate electrode with a margin into an active area on a periphery of the recessed channel;
etching the charge trapping layer to expose recessed channel select gate and margin such that charge trapping layer and recessed channel select gate electrode are substantially not in electrical contact;
forming a select gate over the recessed channel wherein the charge trapping layer is substantially not in electrical contact with the recessed channel select gate; and
forming a word line over the charge trapping layer.

12. The method of forming a memory device of claim 10 further comprising forming a spacer between a recessed channel select gate contact and the charge trapping layer.

13. The method of forming a memory device of claim 2 wherein the spacer comprises tetra-ethyl-ortho-silicate (TEOS) or silicon nitride, or combinations thereof.

14. The method of forming a memory device of claim 2 wherein the spacer substantially separates the charge trapping layer from a contact of the recessed channel select gate.

15. The method of forming a memory device of claim 1 wherein the recessed channel is etched to depth of about 1000 Å to about 1,500 Å.
